(19) United States
(12) Patent Application Publication
(10) Pub. No.: US 2024/0363725 A1
(43) Pub. Date: Oct. 31, 2024

(54) Semiconductor Devices And Methods Of Fabricating The Same

(71) Applicant: Taiwan Semiconductor Manufacturing Company, Ltd., Hsin-Chu (TW)

(72) Inventors: Yu-Ling Hsieh, Pingtung City (TW); Hung-Ju Chou, Hsinchu (TW); Yu-Shan Lu, Hsinchu County (TW); Wei-Yang Lee, Taipei City (TW); Chih-Chung Chang, Hsinchu (TW); Yao-Hsuan Lai, Taoyuan City (TW)

(21) Appl. No.: 18/309,125

(22) Filed: Apr. 28, 2023

(51) Int. Cl. H01L 29/66; H01L 29/06; H01L 29/423; H01L 29/775

(52) U.S. Cl. CPC H01L 29/66439; H01L 29/0673; H01L 29/42392; H01L 29/66545; H01L 29/66553; H01L 29/775

(57) ABSTRACT

Semiconductor devices and methods are provided. An exemplary method according to the present disclosure includes forming a semiconductor fin over a substrate, forming an integral dielectric layer over the substrate, wherein the dielectric layer includes a first portion extending along a sidewall surface of the semiconductor fin and a second portion disposed over the semiconductor fin, a thickness of the second portion of the dielectric layer is greater than a thickness of the first portion of the dielectric layer, forming a dummy gate electrode layer over the substrate, patterning the dielectric layer and the dummy gate electrode layer to form a dummy gate structure over a channel region of the semiconductor fin, forming source/drain features coupled to the channel region of the semiconductor fin and adjacent to the dummy gate structure, and replacing the dummy gate structure with a gate stack.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

For example, as integrated circuit (IC) technologies progress towards smaller technology nodes, multi-gate metal-oxide-semiconductor field effect transistors (multi-gate MOSFETs, or multi-gate devices) have been introduced to improve gate control by increasing gate-channel coupling, reducing off-state current, and reducing short-channel effects (SCEs). A multi-gate device generally refers to a device having a gate structure, or a portion thereof, disposed over more than one side of a channel region. Fin-like field effect transistors (FinFETs) and multi-bridge-channel (MBC) transistors are examples of multi-gate devices that have become popular and promising candidates for high performance and low leakage applications. While existing multi-gate devices are generally adequate for their general purposes, they are not satisfactory in all aspects.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a flowchart of an exemplary method for fabricating a semiconductor device, according to various embodiments of the present disclosure.

FIG. 2 illustrates a perspective view of a semiconductor device during a fabrication stage in the method of FIG. 1, according to aspects of the present disclosure.

FIGS. 3A, 4A, 5A, 6A, 7A, 8A, 9A, 10A, 11A, 12A, 13A, 14A, 15A, 16A, 17A, and 18A, illustrate fragmentary cross-sectional views of an exemplary workpiece during various fabrication stages in the method of FIG. 1, according to one or more aspects of the present disclosure.

FIGS. 3B, 4B, 5B, 6B, 7B, 8B, 9B, 10B, 11B, 12B, 13B, 14B, 15B, 16B, 17B, and 18B illustrate fragmentary cross-sectional views of the exemplary workpiece during various fabrication stages in the method of FIG. 1, according to one or more aspects of the present disclosure.

FIGS. 4C and 10C illustrate fragmentary top views of the exemplary workpiece during a fabrication stage in the method of FIG. 1, according to one or more aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art.

Multi-gate devices are introduced to improve gate control by increasing gate-channel coupling, reducing off-state current, and reducing short-channel effects (SCEs). A multi-gate device generally refers to a device having a gate stack, or portion thereof, disposed over more than one side of a channel region. Fin-like field effect transistors (FinFETs) and multi-bridge-channel (MBC) transistors are examples of multi-gate devices that have become popular and promising candidates for high performance and low leakage applications. A FinFET has an elevated channel wrapped by a gate on more than one side (for example, the gate wraps a top and sidewalls of a “fin” of semiconductor material extending from a substrate). An MBC transistor has a gate stack that can extend, partially or fully, around a channel region to provide access to the channel region on two or more sides. Because its gate stack surrounds the channel regions, an MBC transistor may also be referred to as a surrounding gate transistor (SGT) or a gate-all-around (GAA) transistor. The channel region of an MBC transistor may be formed from nanowires, nanosheets, other nanostructures, and/or other suitable structures. The shapes of the channel region have also given an MBC transistor alternative names such as a nanosheet transistor or a nanowire transistor.

Formation of an MBC transistor includes formation of a semiconductor stack that includes a number of channel layers interleaved by a number of sacrificial layers over a substrate, where the sacrificial layers may be selectively removed to release the channel layers as channel members. A functional gate stack that includes a dielectric layer and a conductive layer is then formed to wrap around and over each of the channel members. In some existing technologies, a gate replacement process (or gate-last process) may be adopted where dummy gate structures serve as placeholders for functional gate stacks. However, during the formation of the dummy gate structures, top and/or sidewall surfaces of the topmost channel layer of those channel layers in the channel regions may be damaged, leading to the topmost channel layer either having an insufficient thickness or a rounded corner, which may disadvantageously affect the epitaxial growth process and the resulted epitaxial source/drain features.

The present disclosure provides semiconductor devices and methods for forming the same. In an embodiment, a method includes forming a fin-shaped active region (e.g., including the patterned semiconductor stack and a portion of the substrate), forming a dummy dielectric layer over the substrate, where a portion of the dummy dielectric layer that is formed over the fin-shaped active region having a thickness greater than a portion of the dummy dielectric layer formed along sidewall surfaces of the fin-shaped active region, forming a dummy gate electrode layer over the dummy dielectric layer, patterning the dummy dielectric layer and the dummy dielectric layer to form a dummy gate structure over a channel region of the active region, and after the forming of source/drain features, selectively removing the dummy gate structure and the sacrificial layers and forming a functional gate stack. By forming the dummy dielectric layer that has a thicker portion over the fin-shaped active region, the topmost channel layer may suffer less loss from its top and corner. Thus, during the formation of the source/drain features, semiconductor layer(s) that may be epitaxially grown from the sidewall surface of the topmost channel layer may have better quality and satisfactory volume. Thus, satisfactory source/drain features may be provided.

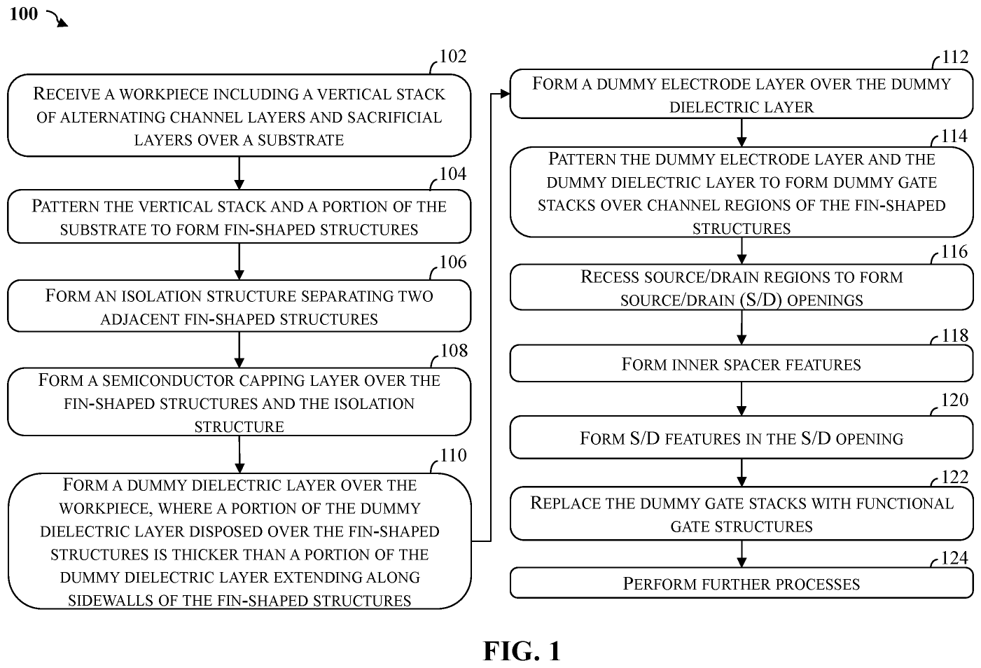

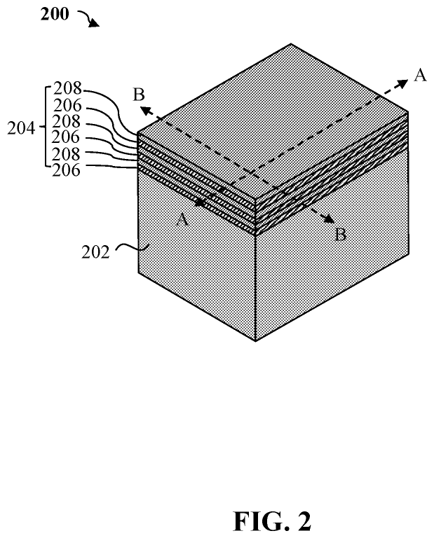

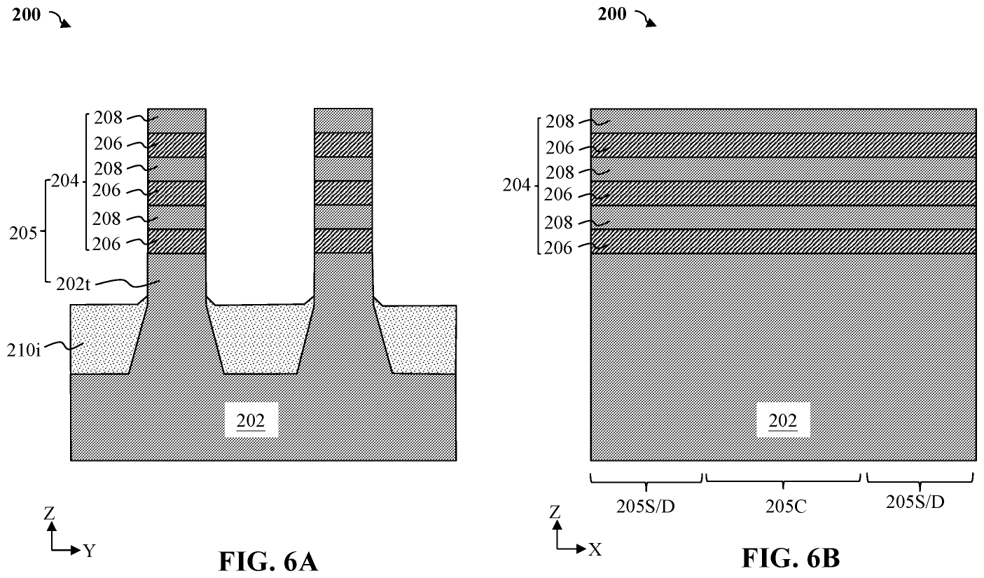

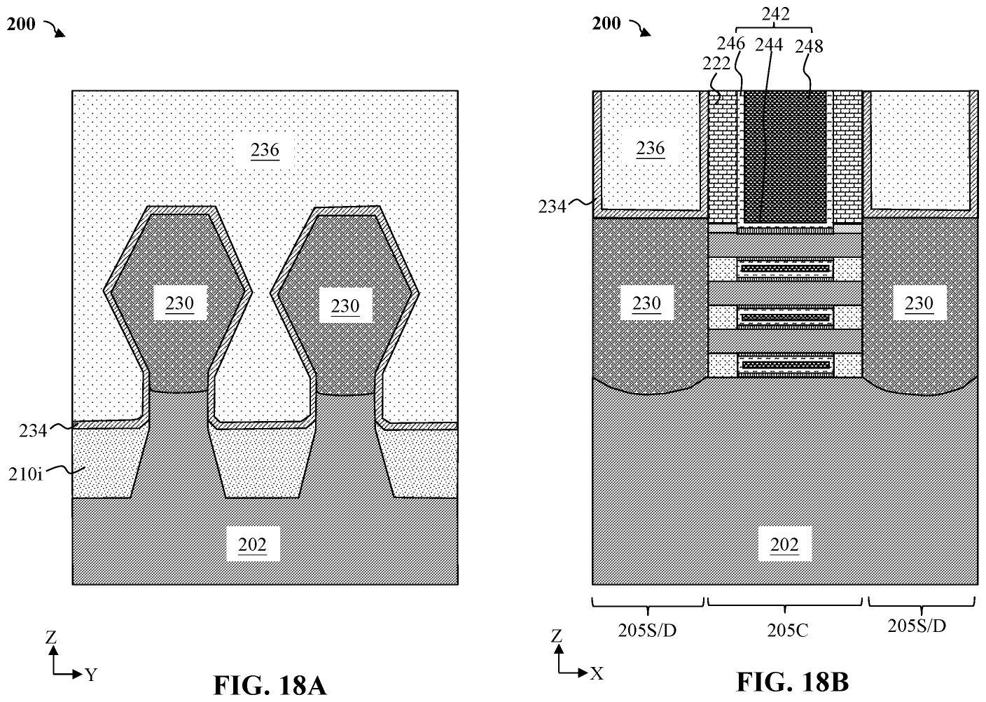

The various aspects of the present disclosure will now be described in more detail with reference to the figures. In that regard, FIG. 1 is a flowchart illustrating method 100 of forming a semiconductor device according to embodiments of the present disclosure. Method 100 is described below in conjunction with FIGS. 2, 3A-18A, 3B-18B, 4C, and 10C, which are fragmentary perspective, top, and/or cross-sectional views of a workpiece 200 at fabrication stages according to embodiments of method 100. Method 100 is merely an example and is not intended to limit the present disclosure to what is explicitly illustrated therein. Additional steps may be provided before, during and after the method 100, and some steps described can be replaced, eliminated, or moved around for additional embodiments of the method. Not all steps are described herein in detail for reasons of simplicity. Because the workpiece 200 will be fabricated into a semiconductor device 200 upon conclusion of the fabrication processes, the workpiece 200 may be referred to as the semiconductor device 200 as the context requires. For avoidance of doubts, the X, Y and Z directions in FIGS. 2-18B are perpendicular to one another and are used consistently throughout FIGS. 2-18B. Throughout the present disclosure, like reference numerals denote like features unless otherwise excepted.

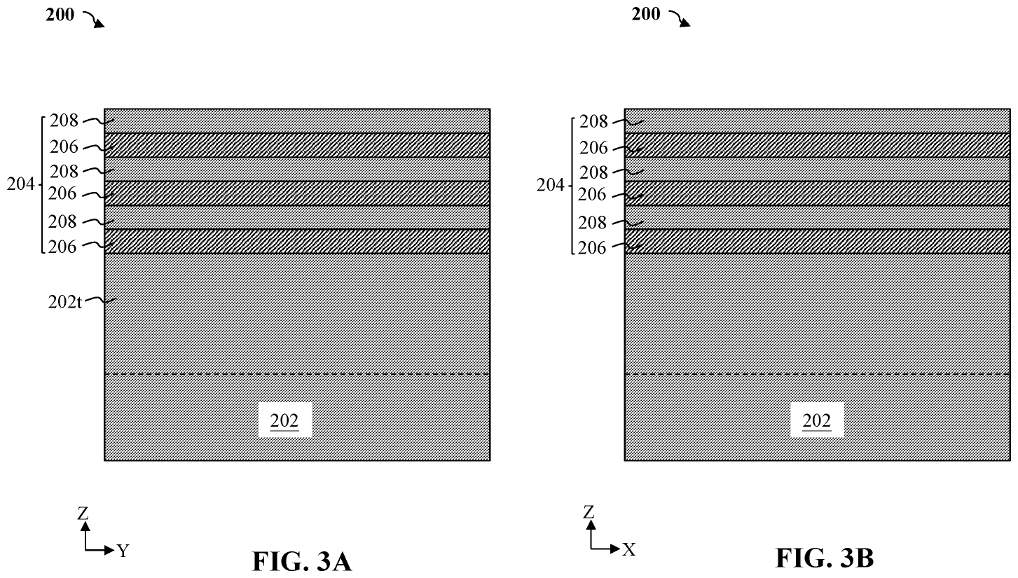

Referring to FIGS. 1, 2 and 3A-3B, method 100 includes a block 102 where a workpiece 200 is received. FIG. 3A illustrates a fragmentary cross-sectional view of the exemplary workpiece 200 taken along line A-A shown in FIG. 2, and FIG. 3B illustrates a fragmentary cross-sectional view of the exemplary workpiece 200 taken along line B-B shown in FIG. 2. The workpiece 200 includes a substrate 202. In an embodiment, the substrate 202 is a bulk silicon substrate (i.e., including bulk single-crystalline silicon). The substrate 202 may include other semiconductor materials in various embodiments, such as germanium, silicon carbide, gallium arsenide, gallium phosphide, indium phosphide, indium arsenide, indium antimonide, SiGe, GaAsP, AlInAs, AlGaAs, GaInAs, GaInP, GaInAsP, or combinations thereof. In some alternative embodiments, the substrate 202 may be a semiconductor-on-insulator substrate, such as a silicon-on-insulator (SOI) substrate, a silicon germanium-on-insulator (SGOI) substrate, or a germanium-on-insulator (GeOI) substrate, and includes a carrier, an insulator on the carrier, and a semiconductor layer on the insulator. The substrate 202 can include various doped regions configured according to design requirements of semiconductor device 200. P-type doped regions may include p-type dopants, such as boron (B), boron difluoride (BF₂), other p-type dopant, or combinations thereof. N-type doped regions may include n-type dopants, such as phosphorus (P), arsenic (As), other n-type dopant, or combinations thereof. The various doped regions can be formed directly on and/or in substrate 202, for example, providing a p-well structure, an n-well structure, or combinations thereof. An ion implantation process, a diffusion process, and/or other suitable doping process can be performed to form the various doped regions.

Still referring to FIG. 2 and FIGS. 3A-3B, the workpiece 200 includes a vertical stack 204 of alternating semiconductor layers disposed over the substrate 202. In an embodiment, the vertical stack 204 includes a number of channel layers 208 interleaved by a number of sacrificial layers 206. Each channel layer 208 may include a semiconductor material such as, silicon, germanium, silicon carbide, silicon germanium, GeSn, SiGeSn, SiGeCSn, other suitable semiconductor materials, or combinations thereof, while each sacrificial layer 206 has a composition different from that of the channel layer 208. In an embodiment, the channel layer 208 includes silicon (Si), the sacrificial layer 206 includes silicon germanium (SiGe). It is noted that three layers of the sacrificial layers 206 and three layers of the channel layers 208 are alternately and vertically arranged as illustrated in FIG. 2 and FIGS. 3A-3B, which are for illustrative purposes only and not intended to limit the present disclosure to what is explicitly illustrated therein. It is understood that any number of sacrificial layers 206 and channel layers 208 can be formed in the stack 204. The number of layers depends on the desired number of channels members for the semiconductor device 200. In some embodiments, the number of the channel layers 208 is between 2 and 10.

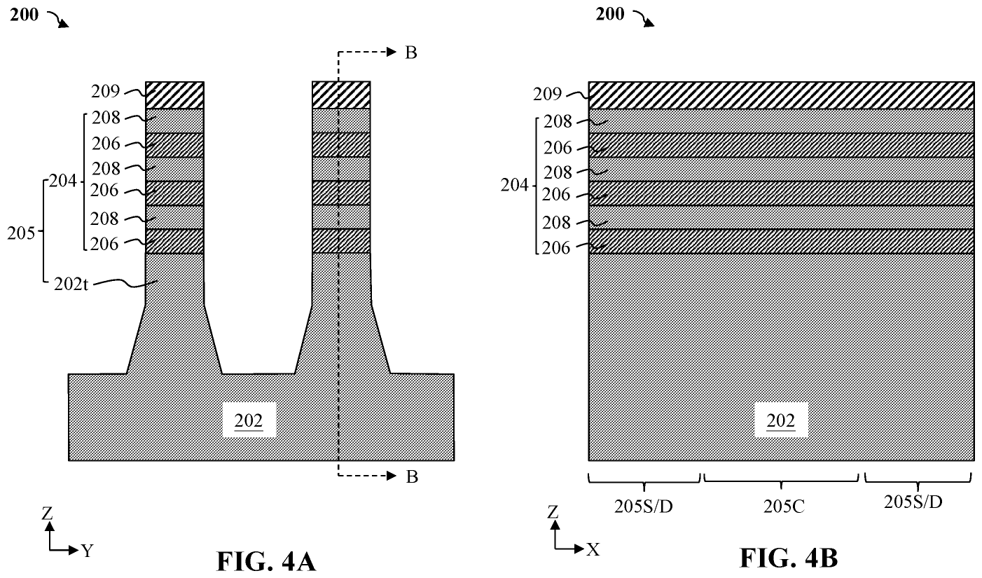

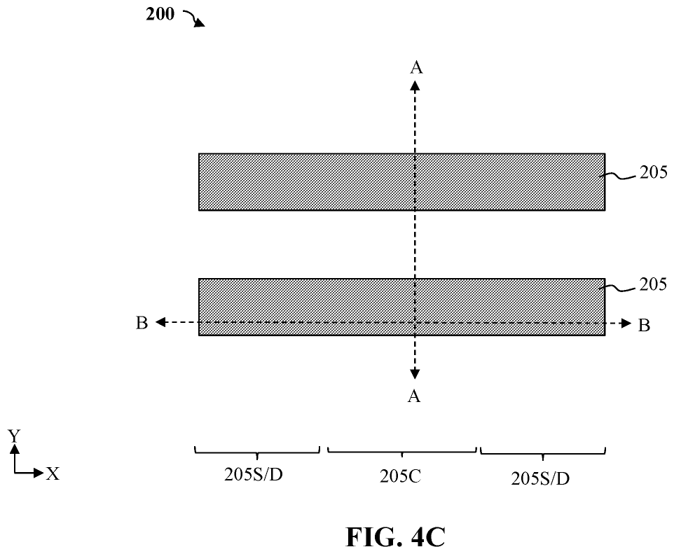

Referring to FIGS. 1 and 4A-4B, method 100 includes a block 104 where the vertical stack 204 and a top portion 202t of the substrate 202 are patterned to form fin-shaped structures 205. A hard mask layer 209 may be formed over the vertical stack 204. The hard mask layer 209 may be a single-layer structure or may include multiple layers. In the present embodiments, the hard mask layer 209 is configured to protect top portions of the fin-shaped structures 205 during subsequent fabrication processes and may include silicon nitride (SiN), silicon oxide (SiO and/or SiO₂), carbon-containing silicon nitride (SiCN), carbon-containing silicon oxide (SiOC), oxygen-containing silicon nitride (SiON), silicon (Si), carbon-and-oxygen-doped silicon nitride (SiOCN), a low-k dielectric material, other suitable materials, or combinations thereof. In one example, the hard mask layer 209 includes silicon nitride.

After forming the hard mask layer 209, the hard mask layer 209 may be patterned. The patterning process may include a lithography process (e.g., photolithography or e-beam lithography) which may further include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. While using the patterned hard mask layer 209 as an etch mask, an etching process may be applied to the vertical stack 204 and the top portion 202t of the substrate 202 to form the fin-shaped structures 205. After the patterning, each of the fin-shaped structures 205 includes a patterned vertical stack 204 and a patterned top portion 202t of the substrate 202. The patterned top portion 202t of the substrate 202 may be referred to as a mesa structure 202t.

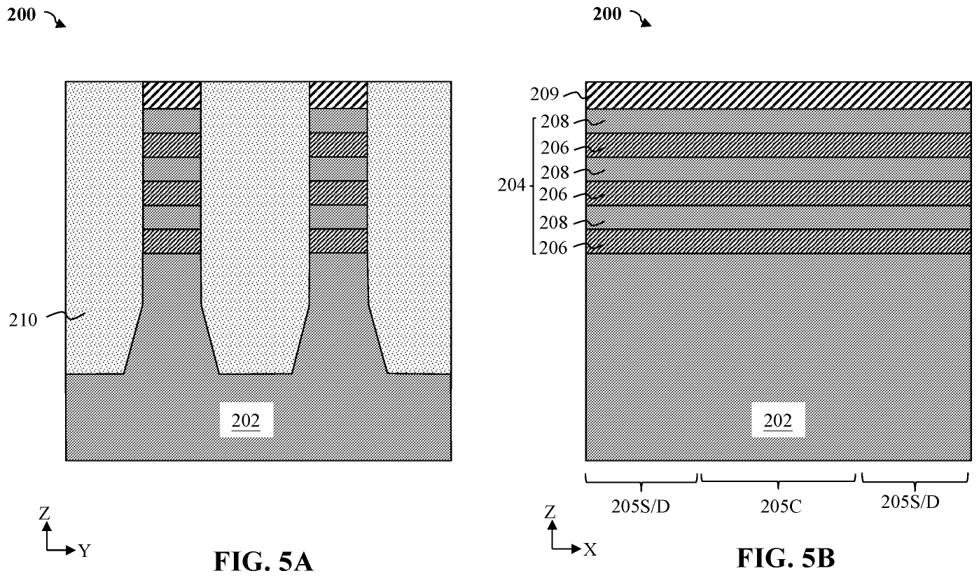

FIG. 4B is a fragmentary cross-sectional view of the workpiece 200 taken along line B-B shown in FIG. 4A. FIG. 4C depict a fragmentary top view of the workpiece 200 shown in FIGS. 4A-4B. As shown in FIGS. 4A-4C, each of the fin-shaped structures 205 extends lengthwise along the Y direction and includes channel regions 205C and source/drain regions 205S/D. Source/drain region(s) may refer to a source region for forming a source in and/or over or a drain region for forming a drain in and/or over, individually or collectively dependent upon the context. Each channel region 205C is disposed between two source/drain regions 205S/D. FIGS. 5A-9A depict cross-sectional views of the workpiece 200 taken along line A-A shown in FIG. 4C during various fabrication stages in the method 100 and FIGS. 5B-9B depict cross-sectional views of the workpiece 200 taken along line B-B shown in FIG. 4C during one of the various fabrication stages in the method 100. It is noted that two fin-shaped structures 205 are formed in as illustrated in FIGS. 4A-4C, which are for illustrative purposes only and not intended to limit the present disclosure to what is explicitly illustrated therein.

Numerous other embodiments of methods for forming the fin-shaped structures 205 may be suitable. For example, the fin-shaped structures 205 may be patterned using double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a dummy layer is formed over a substrate and patterned using a photolithography process. Spacers are formed alongside the patterned dummy layer using a self-aligned process. The dummy layer is then removed, and the remaining spacers, or mandrels, may then be used to pattern the fin-shaped structures 205.

Referring to FIGS. 1, 5A-5B and 6A-6B, method 100 includes a block 106 where an isolation feature 210i is formed to separate (or insulate) bottom portions of the two adjacent fin-shaped structures 205. The isolation feature 210i may include silicon oxide, tetraethylorthosilicate (TEOS), doped silicon oxide (e.g., borophosphosilicate glass (BPSG), fluoride-doped silicate glass (FSG), phosphosilicate glass (PSG), boron-doped silicate glass (BSG), etc.), a low-k dielectric material (having a dielectric constant less than that of silicon oxide, which is about 3.9), other suitable materials, or combinations thereof. The isolation feature 210i may include shallow trench isolation (STI) features. Other isolation feature such as field oxide, local oxidation of silicon (LOCOS), and/or other suitable structures may also be implemented as the isolation feature 210i. In some examples, the isolation feature 210i may include a multi-layer structure, for example, having one or more thermal oxide liner layers. In an embodiment, the isolation feature 210i includes silicon oxide.

In the present embodiments, forming the isolation feature 210i includes depositing an isolating material 210 (shown in FIG. 5A) over the substrate 202, thereby filling the trenches separating the fin-shaped structures 205, applying one or more chemical mechanical planarization (CMP) process to planarize the workpiece 200, and subsequently etching back portions of the isolation material 210 to form the isolation feature 210i, such that the top surface of the isolation feature 210i is below a top surface of the fin-shaped structure 205. The isolating material 210 may be deposited by any suitable method, such as CVD, flowable CVD (FCVD), spin-on-glass (SOG), other suitable methods, or combinations thereof. In an embodiment, the isolating material 210 is formed by FCVD. A curing process (e.g., annealing) may be applied after depositing and/or planarizing the isolation material 210. In some embodiments, as depicted herein, the isolation feature 210i includes a concave surface following the etching back process, where the portion of the top surface of the isolation feature 210i away from sidewalls of the fin-shaped structures 205 is lower than portions closer to the sidewalls of the fin-shaped structures 205. The patterned hard mask layer 209 may be selectively removed after the formation of the isolation feature 210i.

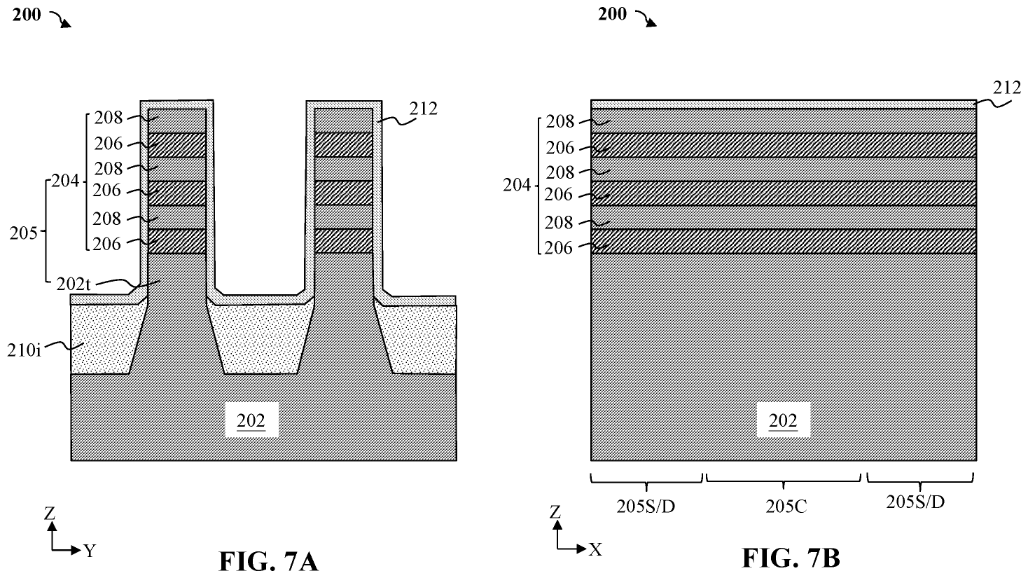

Referring to FIGS. 1 and 7A-7B, method 100 includes a block 108 where a semiconductor capping layer 212 is formed over the fin-shaped structures 205 and the isolation feature 210i. In an embodiment, the semiconductor capping layer 212 is formed of silicon. In an embodiment, the semiconductor capping layer 212 is conformally deposited to have a generally uniform thickness over the top surface of the workpiece 200 (e.g., having about the same thickness on top and sidewall surfaces of the fin-shaped structures 205). The semiconductor capping layer 212 may be deposited using CVD, ALD, or a suitable deposition method. The semiconductor capping layer 212 functions to prevent or reduce diffusion of silicon germanium (SiGe). In some alternative embodiments, operations at block 108 and the semiconductor capping layer 212 they form may be omitted.

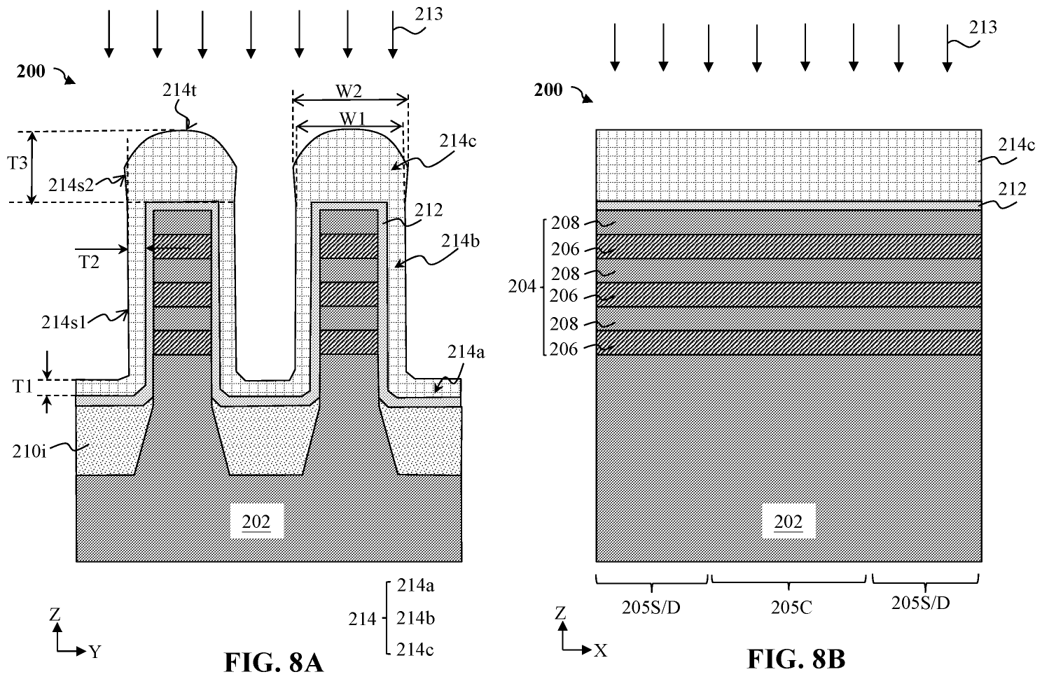

Referring to FIGS. 1 and 8A-8B, method 100 includes a block 110 where a selective deposition process 213 is performed to form a dummy dielectric layer 214 over the workpiece 200. In the present embodiments, to protect the topmost channel layer 208 of the channel layers 208 from being substantially damaged during the formation the dummy gate structures (e.g., the dummy gate structure 220) and thus facilitate the formation of satisfactory source/drain features, the selective deposition process 213 is configured such that a portion of the dummy dielectric layer 214 that is formed over the fin-shaped structures 205 is thicker than the remaining portion of the dummy dielectric layer 214. More specifically, as illustrated in FIG. 8A, the dummy dielectric layer 214 includes a first portion 214a formed directly over the isolation feature 210i and having a generally uniform thickness T1 over the workpiece 200. The dummy dielectric layer 214 also includes a second portion 214b extending along vertical sidewall surfaces of the capping layer 212 and having a generally uniform thickness T2. The dummy dielectric layer 214 also includes a third portion 214c disposed over the second portion 214b of the dummy dielectric layer 214 and the fin-shaped structures 205 and having a thickness T3. In the present embodiments, due to the performing of the selective deposition process 213, the dummy dielectric layer 214 has a convex top surface 214t. The thickness T3 is referred to as a distance between a topmost point of the convex top surface 214t of the dummy dielectric layer 214 and a topmost surface of the capping layer 212. In the present embodiment, due to the deposition condition of the selective deposition process 213, the thickness T3 is greater than the thickness T1 and is also greater than the thickness T2, and the thickness T1 is no less than the thickness T2. In an embodiment, to provide a satisfactory protection to the topmost channel layer 208 of the channel layers 208, a ratio of the thickness T3 to the thickness T2 is greater than 1.5. It is noted that, the dummy dielectric layer 214 is an integral dielectric layer that is formed of a single dielectric material using one single deposition process 213.

In the present embodiments, a sidewalls surface 214s1 of the second portion 214b of the dummy dielectric layer 214 is a substantially vertical surface. The second portion 214b of the dielectric layer 214, the capping layer 212 and the fin-shaped structure 205 collectively span a width W1 along the X direction. The third portion 214c of the dielectric layer 214 is defined by a sidewall surface 214s2 and the convex top surface 214t. The sidewall surface 214s2 is a slanted surface that extends outward from the sidewall surface 214s1 of the second portion 214b of the dielectric layer 214. That is, there is an offset between the sidewall surface 214s1 and the sidewall surface 214s2. Put differently, the third portion 214c overhangs the second portion 214b. The third portion 214c of the dummy dielectric layer 214 spans a width W2 along the X direction, and the width W2 is greater than the width W1.

The dummy dielectric layer 214 may include any suitable dielectric materials. In an embodiment, the dummy dielectric layer 214 includes silicon oxide, and the selective deposition process 213 may include atomic layer deposition (ALD), such as plasma-enhanced ALD (PE-ALD). The dummy dielectric layer 214 with the configuration (e.g., thickness relationships among T1, T2, and T3) described above may be achieved by adjusting one or more parameter of the PE-ALD process, including, though not limited to, pulse time (i.e., duration and/or rate of flow of the precursor material(s)), pulse pressure, pulse energy, and/or pulse frequency when delivering the precursor material(s) for forming the dummy dielectric layer 214. In the present embodiments, precursors of the selective deposition process 213 may include silicon-containing precursors such as an amino alkyl silane and oxygen-containing precursors such as oxygen [O₂]. An example of amino alkyl silane is bis(diethylamino)silane [H₂Si(NC₂H₅)₂] (also known as SAM24). The ALD process for depositing the dummy dielectric layer 214 may also include use of argon (Ar) plasma. In an embodiment, the workpiece 200 is first treated with oxygen in presence of argon plasma and then the silicon-containing precursor is allowed to selectively react with oxygen to deposit on the channel layers 208. In some implementations, the selective deposition process 213 is performed at a temperature between about 200° C. and about 300° C., a pressure maintained in the process chamber during the purging phase is about 1 torr to about 50 torr, and a radio frequency (RF) power level between about 165 W and about 600 W. After the selective deposition of the dummy dielectric layer 214, a plasma treatment with an RF power setting between about 900 W and about 1100 W and a duty cycle between about 5% and about 15% is performed for about 20 seconds to about 40 seconds to densify the dummy dielectric layer.

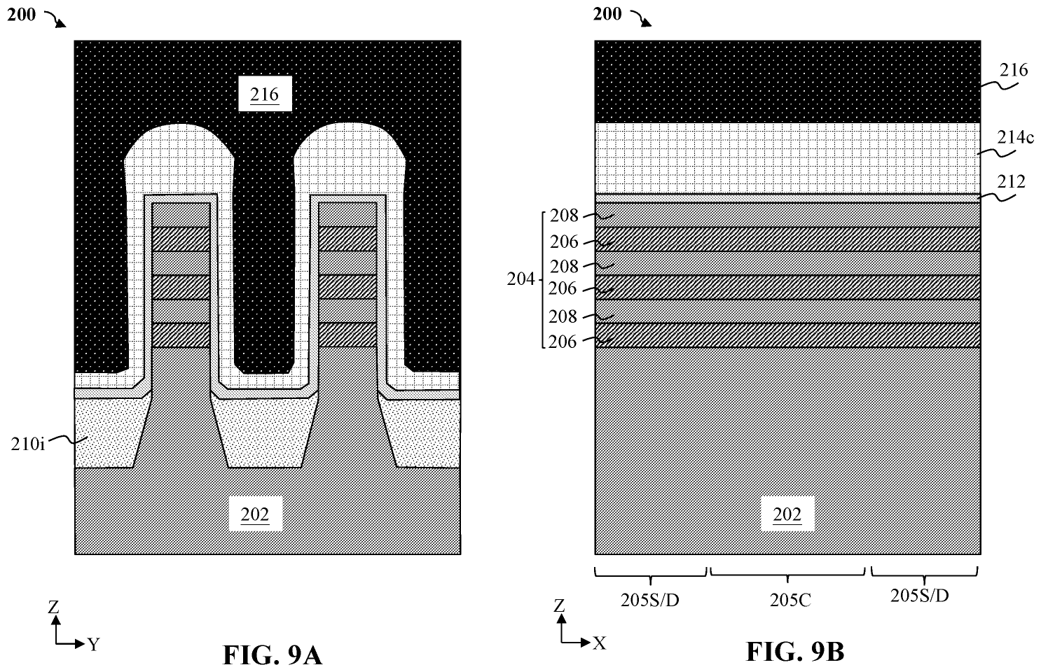

Referring to FIGS. 1 and 9A-9B, method 100 includes a block 112 where a dummy gate electrode layer 216 is formed over the dummy dielectric layer 214. As shown in FIGS. 9A-9B, the dummy gate electrode layer 216 is disposed over the dummy dielectric layer 214. In an embodiment, the dummy gate electrode layer 216 includes polycrystalline silicon (polysilicon). A planarization process may be performed to the dummy gate electrode layer 216 to provide the workpiece 200 a planar top surface.

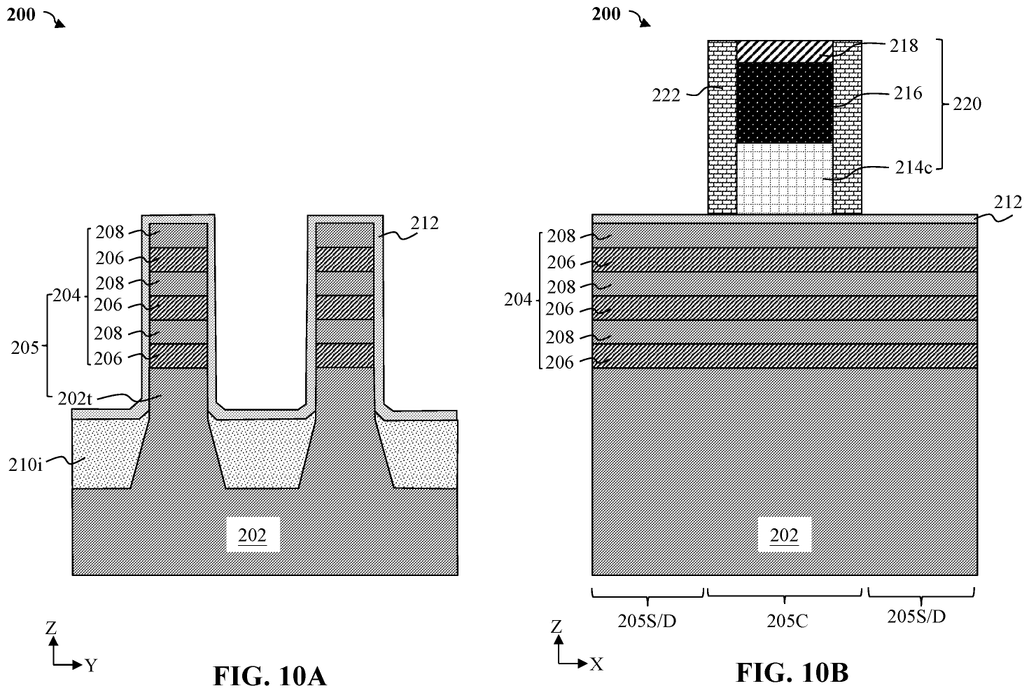

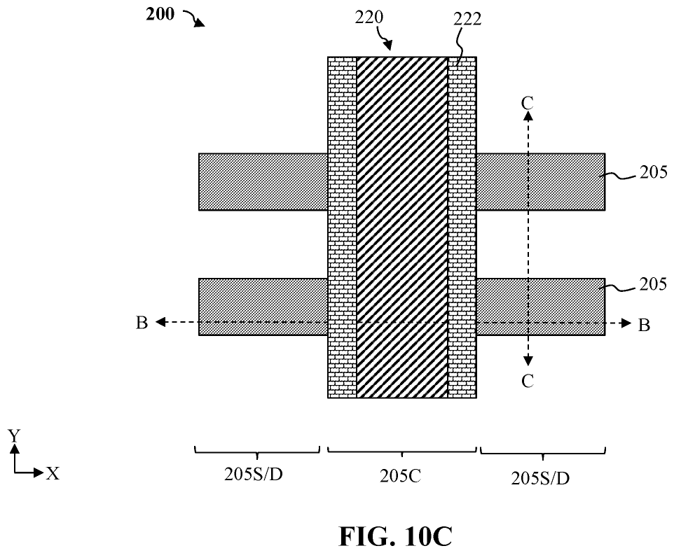

Referring to FIGS. 1, 10A, 10B, and 10C, method 100 includes a block 114 where the dummy gate electrode layer 216 and the dummy dielectric layer 214 are patterned to form dummy gate structures (e.g., dummy gate structure 220) over channel regions 205C of the fin-shaped structures 205. FIG. 10C depicts a fragmentary top view of the workpiece 200 that includes the dummy gate structure 220. FIG. 10A depicts a fragmentary cross-sectional view of the workpiece 200 taken along line C-C shown in FIG. 10C, and FIG. 10B depicts a fragmentary cross-sectional view of the workpiece 200 taken along line B-B shown in FIG. 10C. Before the patterning, a gate-top hard mask layer 218 may be formed over the dummy gate electrode layer 216. The gate-top hard mask layer 218 may be a multi-layer that includes a silicon oxide layer and silicon nitride layer formed on the silicon oxide layer. Suitable deposition process, photolithography and etching process may be employed to pattern the gate-top hard mask layer 218. The patterned gate-top hard mask layer 218 may be then used as an etch mask to pattern the dummy gate electrode layer 216 and the dummy dielectric layer 214. The patterned gate-top hard mask layer 218, the patterned dummy gate electrode layer 216 and patterned the dummy dielectric layer 214 may be collectively referred to as a dummy gate structure 220. In this embodiment, a gate replacement process (or gate-last process) is adopted where the dummy gate structure 220 serves as a placeholder for a functional gate stack. Other processes and configuration are possible.

In the present embodiments, after forming the dummy gate structure 220, gate spacers 222 are formed along sidewall surfaces of the dummy gate structure 220. A gate spacer layer may be deposited conformally over the workpiece 200, including over top and sidewall surfaces of the dummy gate structure 220 and the fin-shaped structure 205. The term “conformally” may be used herein for case of description of a layer having substantially uniform thickness over various regions. The gate spacer layer may be a single-layer structure or a multi-layer structure. The gate spacer layer may be deposited using processes such as, CVD, FCVD, atomic layer deposition (ALD), physical vapor deposition (PVD), or other suitable process. Dielectric materials for the gate spacer may be selected to allow selective removal of the dummy gate structure 220 without substantially damaging the gate spacers 222. The gate spacer layer may include silicon nitride, silicon oxycarbonitride, silicon carbonitride, silicon oxide, silicon oxycarbide, silicon carbide, silicon oxynitride, and/or combinations thereof. The gate spacer layer may be then etched back to form the gate spacers 222 extending along the sidewall surfaces of the dummy gate structure 220.

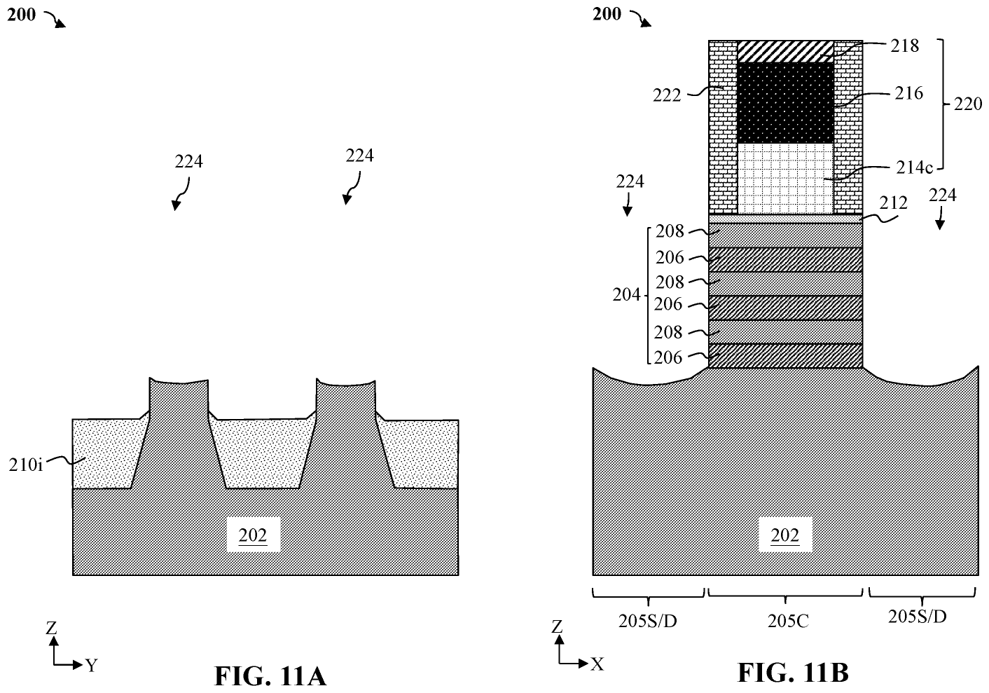

Referring to FIGS. 1 and 11A-11B, method 100 includes a block 116 where source/drain regions 205S/D of the fin-shaped structures 205 are recessed to form source/drain openings 224. With the dummy gate structure 220 and the gate spacer 222 serving as an etch mask, the workpiece 200 is anisotropically etched in the source/drain regions 205S/D of the fin-shaped structures 205 to form source/drain openings 224. The anisotropic etch may include a dry etching process and may implement hydrogen, a fluorine-containing gas (e.g., CF₄, SF₆, CH₂F₂, CHF₃, and/or C₂F₆), a chlorine-containing gas (e.g., Cl₂, CHCl₃, CCl₄, and/or BCl₃), a bromine-containing gas (e.g., HBr and/or CHBr₃), an iodine-containing gas, other suitable gases and/or plasmas, and/or combinations thereof. Source/drain openings 224 may not only extend through the stack 204, but also extend into a portion of the substrate 202. As illustrated in FIG. 11B, sidewalls of the channel layers 208 and the sacrificial layers 206 are exposed in the source/drain openings 224.

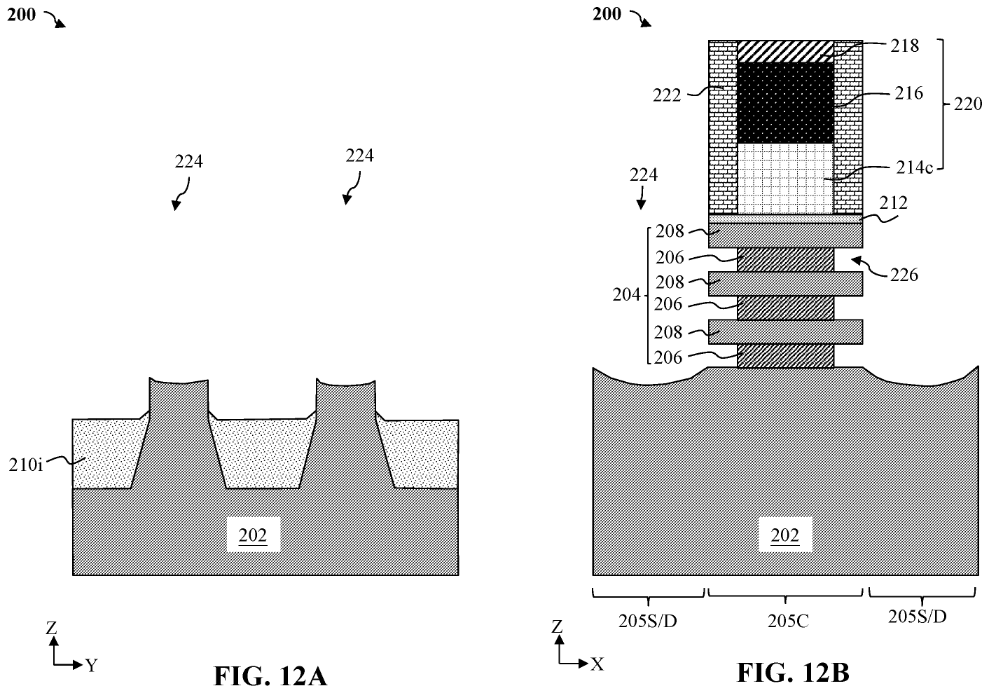

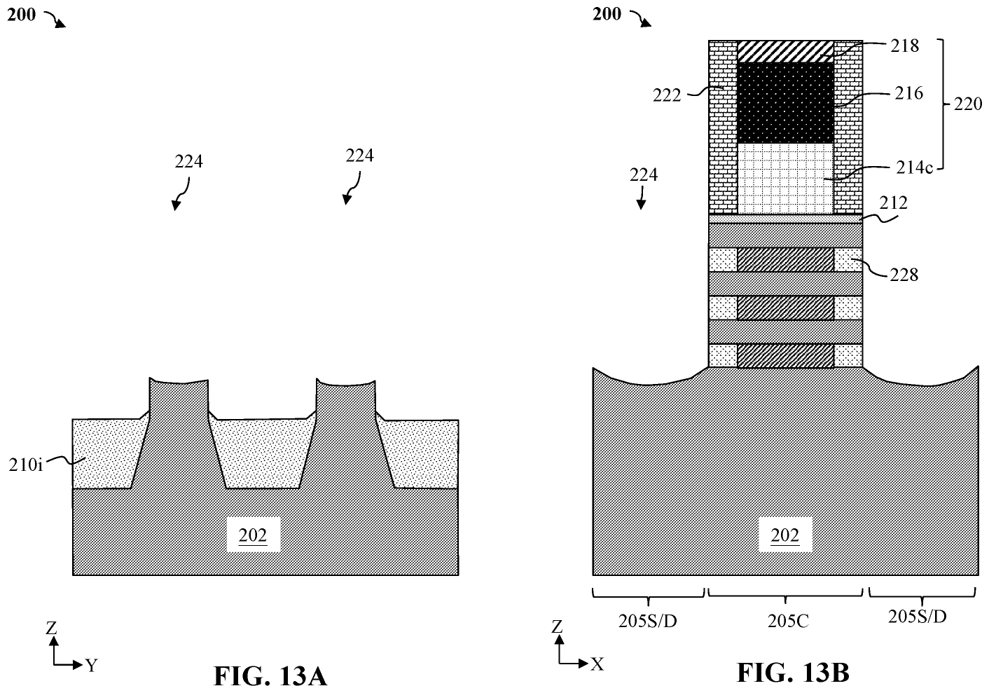

Referring to FIGS. 1, 12A-12B, and 13A-13B, method 100 includes a block 118 where inner spacers features 228 are formed. With reference to FIGS. 12A-12B, after the formation of the source/drain openings 224, the sacrificial layers 206 are exposed. The sacrificial layers 206 are then selectively and partially recessed to form inner spacer recesses 226, while the exposed channel layers 208 are substantially unetched. In an embodiment where the channel layers 208 consist essentially of silicon (Si) and sacrificial layers 206 consist essentially of silicon germanium (SiGe), the selective and partial recess of the sacrificial layers 206 may include use of a selective isotropic etching process (e.g., a selective dry etching process or a selective wet etching process), and the extent at which the sacrificial layers 206 are recessed is controlled by duration of the etching process. After the formation of the inner spacer recesses 226, an inner spacer material layer is deposited over the workpiece 200 using CVD or ALD over the workpiece 200, including in the inner spacer recesses 226. The inner spacer material layer may include silicon oxide, silicon nitride, silicon oxycarbide, silicon oxycarbonitride, silicon carbonitride, metal nitride, or a suitable dielectric material. The deposited inner spacer material layer is then etched back to remove excess inner spacer material layer over sidewalls of the channel layers 208, thereby forming the inner spacer features 228 as shown in FIG. 13B. In some embodiments, the etch back process at block 118 may be a dry etching process and in a way similar to the dry etching process used in the formation of the source/drain openings 224.

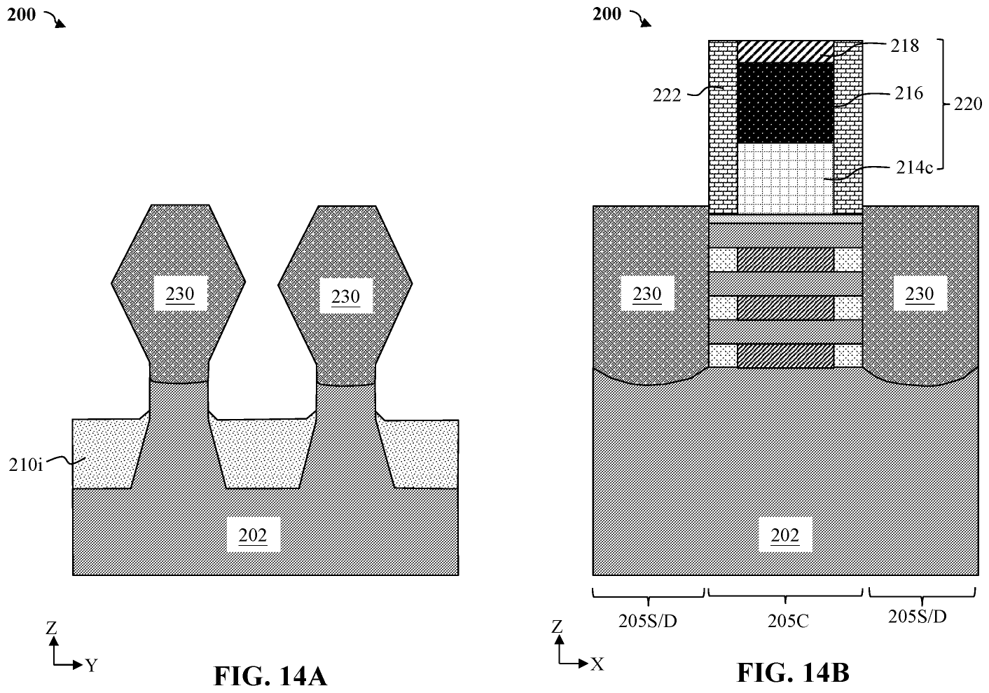

Referring to FIGS. 1 and 14A-14B, method 100 includes a block 120 where source/drain features 230 are formed in the source/drain openings 224. In some embodiments, each of the source/drain features 230 includes a first epitaxial layer (not separately labeled) formed to substantially fill a bottom portion of the source/drain openings 224. The first epitaxial layer is an undoped or unintentionally doped (UID) epitaxial layer that is substantially free of dopants. The first epitaxial layer includes undoped silicon, undoped germanium, undoped silicon germanium, undoped silicon carbide, other suitable semiconductor materials, or combinations thereof. In some embodiments, the first epitaxial layer is formed using a cyclic deposition etch (CDE) process, which is a sequence of deposition processes and etch processes configured to alternately deposit and etch a semiconductor material. Each cycle of the CDE process includes a deposition process and an etching process, where the CDE process implements multiple cycles to form the first epitaxial layer. In some implementations, the deposition process is a chemical vapor deposition (CVD) process configured to epitaxially grow a semiconductor material.

In some embodiments, each of the source/drain features 230 also includes a second epitaxial layer (not separately labeled) formed in the source/drain openings 224 and over the first epitaxial layer. The second epitaxial layer may be selectively grown from semiconductor surfaces exposed in the source/drain openings 224 by using an epitaxial process, such as VPE, UHV-CVD, MBE, and/or other suitable processes. The epitaxial process may use gaseous and/or liquid precursors, which interact with the composition of the first epitaxial layer and/or the channel layers 208. In the present embodiments, the second epitaxial layer is formed over sidewalls of the channel layers 208 and a top surface of the first epitaxial layer exposed in the source/drain openings 224, thereby partially filling the source/drain openings 224. Since the topmost channel layer 208 is not substantially damaged during the formation of the dummy gate structure 220 due to the non-uniform dummy dielectric layer 214, the second epitaxial layer selectively grown from sidewall surface of the channel layers 208 exposed in the source/drain openings 224 may have a satisfactory volume and better topology. A composition of the second epitaxial layer is different than a composition of the first epitaxial layer. More specifically, in embodiments where the workpiece 200 includes n-type transistors, the second epitaxial layer may include arsenic-doped silicon (Si:As), phosphorus-doped silicon (Si:P), or other suitable materials, and have a first dopant concentration greater than that of the undoped first epitaxial layer. In embodiments where the workpiece 200 includes p-type transistors, the second epitaxial layer may include boron-doped silicon germanium (SiGe:B), boron-doped silicon carbide (SiC:B), or other suitable materials, and have a first dopant concentration greater than that of the undoped first epitaxial layer.

In some embodiments, each of the source/drain features 230 also includes a third epitaxial layer (not separately labeled) is formed over the second epitaxial layer to substantially fill the source/drain openings 224. The third epitaxial layer may be formed over the first and the second epitaxial layers by using an epitaxial process, such as VPE, UHV-CVD, MBE, and/or other suitable processes. The third epitaxial layer may be separated from the channel layers 208 and the inner spacer features 228 by a sidewall epitaxial portion of the second epitaxial layer. Depending on the conductivity type of the to-be-formed transistor, the third epitaxial layer may be an n-type feature or a p-type an n-type feature. A composition of the third epitaxial layer may be the same as or different than a composition of the second epitaxial layer, and a dopant concentration of the third epitaxial layer is greater than that of the second epitaxial layer. More specifically, in embodiments where the workpiece 200 includes n-type transistors, the third epitaxial layer may include arsenic-doped silicon (Si:As), phosphorus-doped silicon (Si:P), or other suitable materials, and have a second dopant concentration greater than the first dopant concentration. In an embodiment, the second epitaxial layer is formed of arsenic-doped silicon (Si:As), and the third epitaxial layer is formed of phosphorus-doped silicon (Si:P). In embodiments where the workpiece 200 includes p-type transistors, the third epitaxial layer may include boron-doped silicon germanium (SiGe:B), boron-doped silicon carbide (SiC:B), or other suitable materials, and have a second dopant concentration greater than the first dopant concentration.

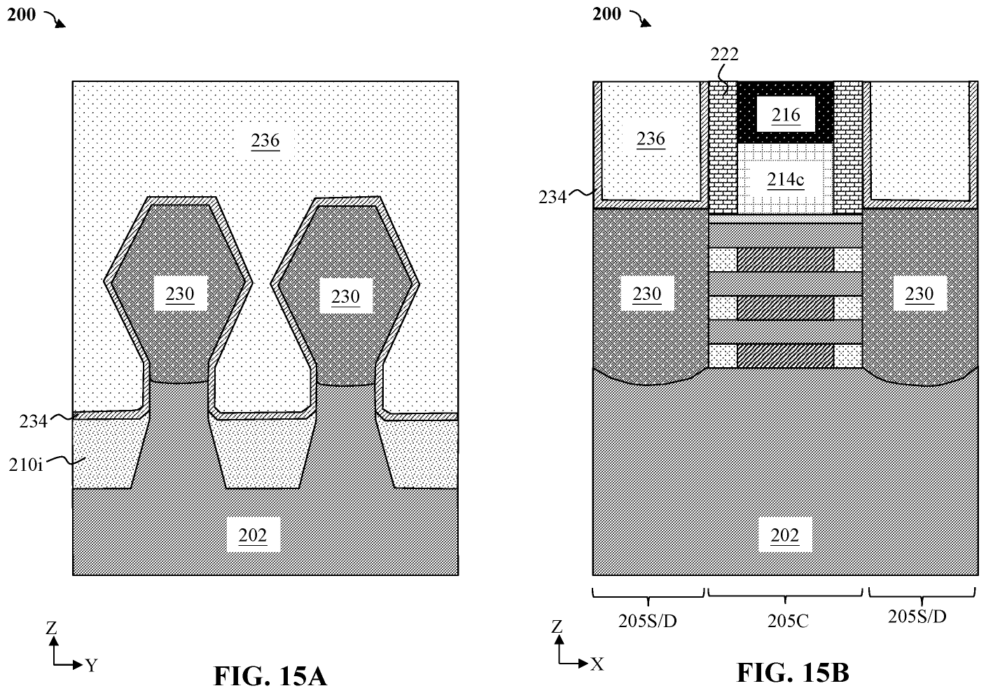

Referring to FIGS. 1, 15A-18A, and 15B-18B, method 100 includes a block 122 where the dummy gate structure 220 is replaced by a functional gate stack 242. With reference to FIGS. 15A-15B, a contact etch stop layer (CESL) 234 and an interlayer dielectric layer (ILD) layer 236 are deposited over the workpiece 200. The CESL 234 may include silicon nitride, silicon oxynitride, and/or other materials known in the art and may be formed by ALD, plasma-enhanced chemical vapor deposition (PECVD) process and/or other suitable deposition or oxidation processes. As shown in FIGS. 15A-15B, the CESL 234 may be deposited on top and sidewall surfaces of the source/drain features 230 and sidewall surface of the gate spacer 222. The ILD layer 236 may be deposited by a PECVD process or other suitable deposition technique over the workpiece 200 after the deposition of the CESL 234. The ILD layer 236 may include materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. In some embodiments, after formation of the ILD layer 236, the workpiece 200 may be annealed to improve integrity of the ILD layer 236.

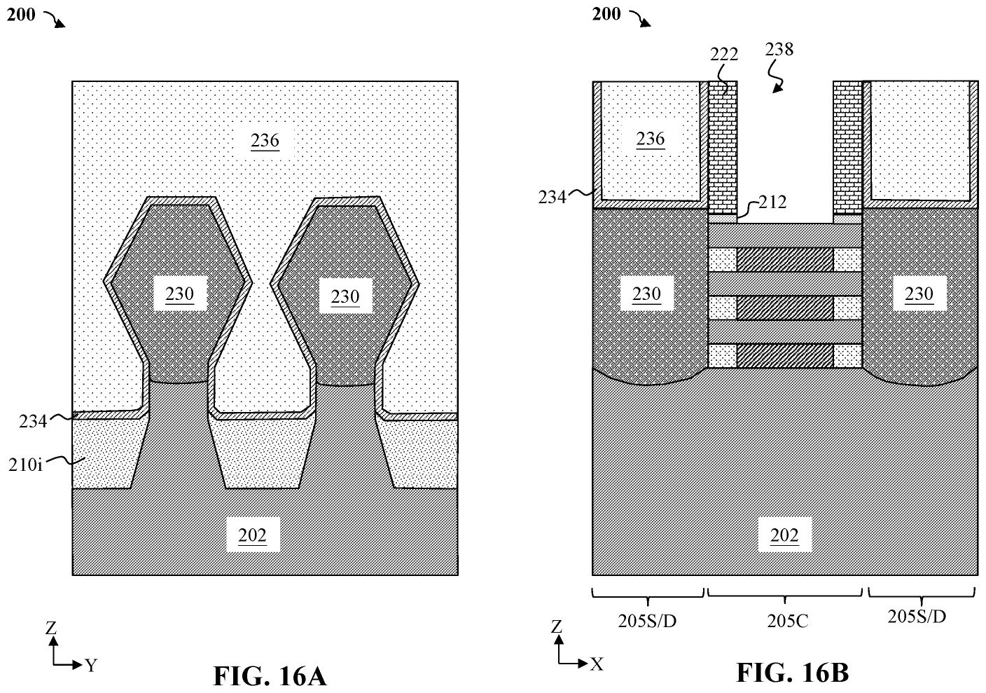

After the formation of the ILD layer 236, a planarization process, such a chemical mechanical polishing (CMP) process may be performed to the workpiece 200 to remove excess materials and expose the top surface of the dummy gate electrode layer 216. With the exposure of the dummy gate electrode layer 216, as depicted in FIGS. 16A-16B, block 122 proceeds to removal of the dummy gate electrode layer 216 and the dummy dielectric layer 214. The removal may include one or more etching process that are selective to the material in the dummy gate structure 220. For example, the removal of the dummy gate structure 220 may be performed using one or more selective wet etch, one or more selective dry etch, or combinations thereof. In some embodiments represented in the drawings, the removal of the dummy gate structure 220 also removes the capping layer 212 not covered by the gate spacers 222. The removal of the dummy gate structure 220 forms a gate trench 238 that exposes sidewalls of the sacrificial layers 206 and the channel layers 208 in the channel regions 205C.

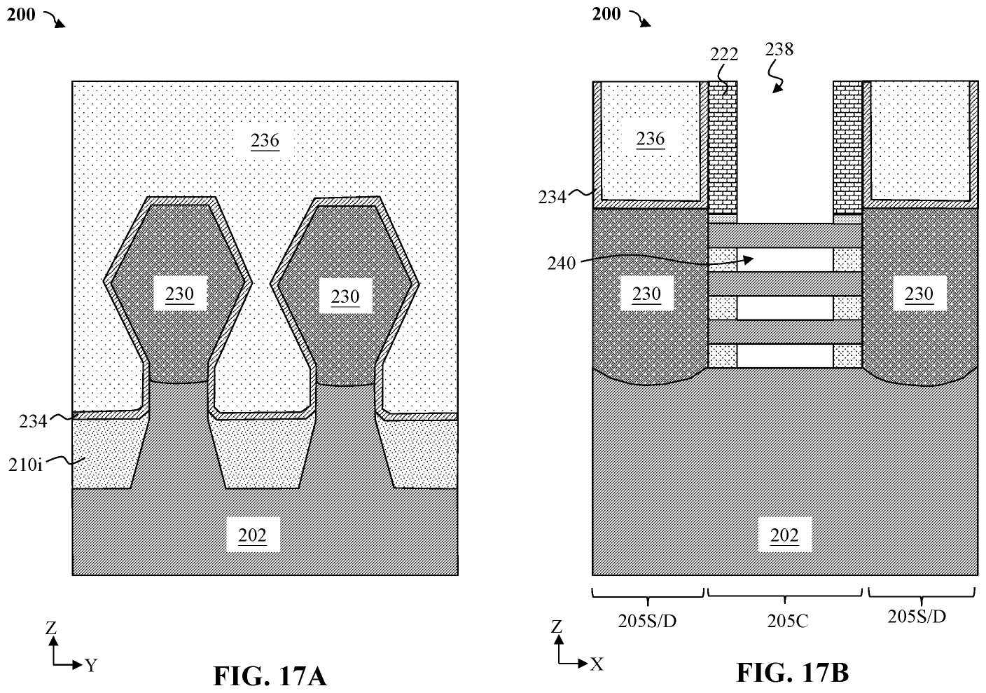

After the removal of the dummy gate structure 220, block 122 proceeds to removal of the sacrificial layers 206. As depicted in FIGS. 17A-17B, the sacrificial layers 206 are selectively removed to release the channel layers 208 as channel members 208 in the channel regions 205C. The selective removal of the sacrificial layers 206 may be implemented by a selective dry etch, a selective wet etch, or other selective etching process. In some embodiments, the selective wet etching includes an APM etch (e.g., ammonia hydroxide-hydrogen peroxide-water mixture). The selective removal of the sacrificial layers 206 forms a number of gate openings 240.

With respect to FIGS. 19A-19B, a functional gate stack 242 is formed in the gate trench 238 and in the gate openings 240 to wrap over the channel members 208. The gate stack 242 includes a gate dielectric layer and a gate electrode layer 248 over the gate dielectric layer. In some embodiments, the gate dielectric layer includes an interfacial layer 244 disposed over the channel members 208 and a high-k dielectric layer 246 over the interfacial layer 244. In some embodiments, the interfacial layer 244 includes silicon oxide and may be formed by a thermal oxidation process. For example, a portion of the channel members 208 exposed in the gate trench 238 may be oxidized to form the interfacial layer 244 in the gate trench 238. Similarly, surfaces of the channel layers 208 exposed by the gate openings 240 may be oxidized to form the interfacial layer 244 in the gate openings 240. The high-k dielectric layer 246 is then deposited over the interfacial layer 244 using ALD, CVD, and/or other suitable methods. Here, a high-k dielectric layer 246 refers to a dielectric material having a dielectric constant greater than that of silicon dioxide, which is about 3.9. The high-k dielectric layer 246 may include hafnium oxide. Alternatively, the high-k dielectric layer 246 may include other high-k dielectrics, such as titanium oxide, hafnium zirconium oxide, tantalum oxide, hafnium silicon oxide, zirconium silicon oxide, lanthanum oxide, aluminum oxide, yttrium oxide, SrTiO₃, BaTiO₃, BaZrO, hafnium lanthanum oxide, lanthanum silicon oxide, aluminum silicon oxide, hafnium tantalum oxide, hafnium titanium oxide, (Ba,Sr)TiO₃ (BST), silicon nitride, silicon oxynitride, combinations thereof, or other suitable material.

The gate electrode layer 248 is then deposited over the gate dielectric layer using ALD, PVD, CVD, e-beam evaporation, or other suitable methods. The gate electrode layer 248 may include a single layer or alternatively a multi-layer structure, such as various combinations of a metal layer with a selected work function to enhance the device performance (work function metal layer), a liner layer, a wetting layer, an adhesion layer, a metal alloy or a metal silicide. By way of example, the gate electrode layer 248 may include titanium nitride, titanium aluminum, titanium aluminum nitride, tantalum nitride, tantalum aluminum, tantalum aluminum nitride, tantalum aluminum carbide, tantalum carbonitride, aluminum, tungsten, nickel, titanium, ruthenium, cobalt, platinum, tantalum carbide, tantalum silicon nitride, copper, other refractory metals, or other suitable metal materials or a combination thereof. Further, where the semiconductor device 200 includes n-type transistors and p-type transistors, different gate electrode layers may be formed separately for n-type transistors and p-type transistors, which may include different work function metal layers (e.g., for providing different n-type and p-type work function metal layers).

Referring to FIG. 1, method 100 includes a block 124 where further processes may be performed to complete the fabrication of the semiconductor device 200. For example, method 100 may further include recessing the gate stack 242, forming dielectric capping layer over the recessed gate stack 242. Such further processes may also include forming an interconnect structure configured to connect the various features to form a functional circuit that includes the different semiconductor devices. The interconnect structure may include multiple interlayer dielectric (ILD) layers and multiple metal lines, contact vias, and/or power rails in each of the ILD layers. The metal lines, contact vias, and/or power rails in each ILD layer may be formed of metal, such as aluminum, tungsten, ruthenium, or copper.

Although not intended to be limiting, one or more embodiments of the present disclosure provide many benefits to a semiconductor device and the formation thereof. For example, the present disclosure provides a dummy dielectric layer having a non-uniform thickness and a dummy gate electrode layer over the dummy dielectric layer. More specifically, a portion of the dummy dielectric layer formed over fin-shaped active regions is thicker than a remaining portion of the dummy dielectric layer to protect a topmost channel layer from being substantially damaged during the patterning of the dummy dielectric layer and the dummy gate electrode layer. Embodiments of the disclosed methods can be readily integrated into existing processes and technologies for manufacturing GAAs and FinFETs.

The present disclosure provides for many different embodiments. Semiconductor devices and methods of fabrication thereof are disclosed herein. In one exemplary aspect, the present disclosure is directed to a method. The method includes forming a semiconductor fin over a substrate, forming an integral dielectric layer over the substrate, wherein the dielectric layer includes a first portion extending along a sidewall surface of the semiconductor fin and a second portion disposed over the semiconductor fin, a thickness of the second portion of the dielectric layer is greater than a thickness of the first portion of the dielectric layer, forming a dummy gate electrode layer over the substrate, patterning the dielectric layer and the dummy gate electrode layer to form a dummy gate structure over a channel region of the semiconductor fin, forming source/drain features coupled to the channel region of the semiconductor fin and adjacent to the dummy gate structure, and replacing the dummy gate structure with a gate stack.

In some embodiments, a ratio of the thickness of the second portion of the dielectric layer to the thickness of the first portion of the dielectric layer is greater than 1.5. In some embodiments, the method may further include forming an isolation feature configured to isolate a bottom portion of the semiconductor fin from an adjacent semiconductor fin. The dielectric layer further includes a third portion disposed directly over the isolation feature, and a thickness of the third portion of the dielectric layer is less than the thickness of the second portion of the dielectric layer. In some implementations, the thickness of the third portion of the dielectric layer is greater than or substantially equal to the thickness of the first portion of the dielectric layer. In some instances, the second portion of the dielectric layer includes a convex top surface. In some embodiments, a sidewall of the second portion of the dielectric layer is offset from a sidewall of the first portion of the dielectric layer. In some embodiments, the method may further include before the forming of the integral dielectric layer, conformally forming a semiconductor layer over the substrate. In some embodiments, the integral dielectric layer includes silicon oxide, and the forming of the integral dielectric layer includes utilizing amino alkyl silane as precursors. In some instances, the forming of the integral dielectric layer includes a process pressure between about 1 torr and about 50 torr. In some implementations, the forming of the source/drain features includes recessing portions of the semiconductor fin not covered by the dummy gate structure to form source/drain openings, and epitaxially growing one or more semiconductor layer in the source/drain openings.

In another exemplary aspect, the present disclosure is directed to a method. The method includes forming a vertical stack of alternating first semiconductor layers and second semiconductor layers over a substrate, patterning the vertical stack and a portion of the substrate to form a first fin-shaped structure and a second fin-shaped structure, forming an isolation feature to isolate the first and second fin-shaped structures, depositing an oxide layer over the substrate, wherein the oxide layer includes a first portion disposed directly over the isolation feature and a second portion disposed over the first and second fin-shaped structures, and a thickness of the second portion of the oxide layer is different than a thickness of the first portion of the oxide layer; forming a gate electrode layer over the oxide layer, removing a portion of the oxide layer and a portion of the gate electrode layer to form a gate structure over channel regions of the first and second fin-shaped structures, forming source/drain features adjacent to the gate structure, selectively removing the gate structure; selectively removing the second semiconductor layers, and forming a gate stack wrapping around and over the first semiconductor layers.

In some embodiments, the method may further include before the depositing of the oxide layer, conformally forming a third semiconductor layer over the substrate, wherein a composition of the third semiconductor layer is the same as a composition of the first semiconductor layers. In some embodiments, the depositing of the oxide layer includes use of bis(diethylamino)silane. In some implementations, the oxide layer further includes a third portion extending along sidewall surfaces of the first and second fin-shaped structures. In some instances, a ratio of a thickness of the second portion of the oxide layer to a thickness of the third portion of the oxide layer is greater than 1.5. In some embodiments, the second portion of the oxide layer overhangs the third portion of the oxide layer.

In yet another exemplary aspect, the present disclosure is directed to a method. The method includes providing a workpiece including a first fin-shaped active region and a second fin-shaped active region over a substrate and separated by an isolation feature, performing a selective deposition process to form a dummy gate dielectric layer over the workpiece, wherein a thickness of the dummy gate dielectric layer is non-uniform across the workpiece, forming a dummy gate electrode layer over the dummy gate dielectric layer, performing an etching process to pattern the dummy gate dielectric layer and the dummy gate electrode layer to form a dummy gate structure over channel regions of the first and second fin-shaped active regions, after the performing of the etching process, forming source/drain features adjacent to the dummy gate structure, and replacing the dummy gate structure with a gate stack.

In some embodiments, each of the first active region and the second active region includes a vertical stack of semiconductor layers and a portion of the substrate directly under the vertical stack of semiconductor layers, the vertical stack of semiconductor layers including a plurality of alternating channel layers and sacrificial layers. In some implementations, the method may further include after the forming of the source/drain features, selectively removing the sacrificial layers. The gate stack further wraps around each channel layer of the channel layers. In some embodiments, the dummy gate dielectric layer include a first portion extending along sidewall surfaces of the first and second fin-shaped active regions and a second portion disposed over the first and second fin-shaped active regions, a thickness of the second portion of the dummy gate dielectric layer is greater than a thickness of the first portion of the dummy gate dielectric layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a semiconductor fin over a substrate;
forming an integral dielectric layer over the substrate, wherein the dielectric layer comprises a first portion extending along a sidewall surface of the semiconductor fin and a second portion disposed over the semiconductor fin, a thickness of the second portion of the dielectric layer is greater than a thickness of the first portion of the dielectric layer;
forming a dummy gate electrode layer over the substrate;
patterning the dielectric layer and the dummy gate electrode layer to form a dummy gate structure over a channel region of the semiconductor fin;
forming source/drain features coupled to the channel region of the semiconductor fin and adjacent to the dummy gate structure; and
replacing the dummy gate structure with a gate stack.

2. The method of claim 1, wherein a ratio of the thickness of the second portion of the dielectric layer to the thickness of the first portion of the dielectric layer is greater than 1.5.

3. The method of claim 1, further comprising:
forming an isolation feature configured to isolate a bottom portion of the semiconductor fin from an adjacent semiconductor fin,
wherein the dielectric layer further comprises a third portion disposed directly over the isolation feature, and a thickness of the third portion of the dielectric layer is less than the thickness of the second portion of the dielectric layer.

4. The method of claim 3, wherein the thickness of the third portion of the dielectric layer is greater than or substantially equal to the thickness of the first portion of the dielectric layer.

5. The method of claim 1, wherein the second portion of the dielectric layer comprises a convex top surface.

6. The method of claim 1, wherein a sidewall of the second portion of the dielectric layer is offset from a sidewall of the first portion of the dielectric layer.

7. The method of claim 1, further comprising:
before the forming of the integral dielectric layer, conformally forming a semiconductor layer over the substrate.

8. The method of claim 1, wherein the integral dielectric layer comprises silicon oxide, and the forming of the integral dielectric layer comprises utilizing amino alkyl silane as precursors.

9. The method of claim 8, wherein the forming of the integral dielectric layer comprises a process pressure between about 1 torr and about 50 torr.

10. The method of claim 1, wherein the forming of the source/drain features comprises:
recessing portions of the semiconductor fin not covered by the dummy gate structure to form source/drain openings; and
epitaxially growing one or more semiconductor layer in the source/drain openings.

11. A method, comprising:
forming a vertical stack of alternating first semiconductor layers and second semiconductor layers over a substrate;
patterning the vertical stack and a portion of the substrate to form a first fin-shaped structure and a second fin-shaped structure;
forming an isolation feature to isolate the first and second fin-shaped structures;
depositing an oxide layer over the substrate, wherein the oxide layer comprises a first portion disposed directly over the isolation feature and a second portion disposed over the first and second fin-shaped structures, and a thickness of the second portion of the oxide layer is different than a thickness of the first portion of the oxide layer;
forming a gate electrode layer over the oxide layer;
removing a portion of the oxide layer and a portion of the gate electrode layer to form a gate structure over channel regions of the first and second fin-shaped structures;
forming source/drain features adjacent to the gate structure;
selectively removing the gate structure;
selectively removing the second semiconductor layers; and
forming a gate stack wrapping around and over the first semiconductor layers.

12. The method of claim 11, further comprising:
before the depositing of the oxide layer, conformally forming a third semiconductor layer over the substrate, wherein a composition of the third semiconductor layer is the same as a composition of the first semiconductor layers.

13. The method of claim 11, wherein the depositing of the oxide layer comprises use of bis(diethylamino)silane.

14. The method of claim 11, wherein the oxide layer further comprises a third portion extending along sidewall surfaces of the first and second fin-shaped structures.

15. The method of claim 14, wherein a ratio of a thickness of the second portion of the oxide layer to a thickness of the third portion of the oxide layer is greater than 1.5.

16. The method of claim 14, wherein the second portion of the oxide layer overhangs the third portion of the oxide layer.

17. A method, comprising:
providing a workpiece comprising a first fin-shaped active region and a second fin-shaped active region over a substrate and separated by an isolation feature;
performing a selective deposition process to form a dummy gate dielectric layer over the workpiece, wherein a thickness of the dummy gate dielectric layer is non-uniform across the workpiece;
forming a dummy gate electrode layer over the dummy gate dielectric layer;
performing an etching process to pattern the dummy gate dielectric layer and the dummy gate electrode layer to form a dummy gate structure over channel regions of the first and second fin-shaped active regions;
after the performing of the etching process, forming source/drain features adjacent to the dummy gate structure; and
replacing the dummy gate structure with a gate stack.

18. The method of claim 17, wherein each of the first active region and the second active region includes a vertical stack of semiconductor layers and a portion of the substrate directly under the vertical stack of semiconductor layers, the vertical stack of semiconductor layers comprising a plurality of alternating channel layers and sacrificial layers.

19. The method of claim 18, further comprising:
after the forming of the source/drain features, selectively removing the sacrificial layers;
wherein the gate stack further wraps around each channel layer of the channel layers.

20. The method of claim 17, wherein the dummy gate dielectric layer comprises a first portion extending along sidewall surfaces of the first and second fin-shaped active regions and a second portion disposed over the first and second fin-shaped active regions, a thickness of the second portion of the dummy gate dielectric layer is greater than a thickness of the first portion of the dummy gate dielectric layer.
